(19) United States
(12) Patent Application Publication
(10) Pub. No.: US 2022/0367822 A1
(43) Pub. Date: Nov. 17, 2022

(54) FOLDABLE DISPLAY PANEL WITH IMPROVED IMPACT RESISTANCE

(71) Applicant: SHARP KABUSHIKI KAISHA, Osaka (JP)

(72) Inventor: EDWARD ANDREW BOARDMAN, Abingdon (GB)

(21) Appl. No.: 17/320,031

(22) Filed: May 13, 2021

(51) Int. Cl. H01L 51/00; H01L 27/32; H01L 51/52; B32B 7/12; B32B 7/023; B32B 7/022; B32B 27/36; B32B 27/28; B32B 27/30; B32B 27/08; C08J 5/12; C08J 5/18

(52) U.S. Cl. CPC H01L 51/0097; H01L 27/323; H01L 27/3244; H01L 51/524; H01L 51/5281; B32B 7/12; B32B 7/023; B32B 7/022; B32B 27/36; B32B 27/281; B32B 27/308; B32B 27/08; C08J 5/124; C08J 5/18; H01L 2251/5338; B32B 2457/206; B32B 2307/42; B32B 2457/208; B32B 2307/54; C08J 2367/02; C08J 2333/12; C08J 2379/08; C08J 2345/00

(57) ABSTRACT

A foldable display device includes an organic light emitting diode (OLED) display substrate, a stress relief layer parallel with the OLED display substrate, and a first adhesive layer between the OLED display substrate and the stress relief layer. A value of v/E of the OLED display substrate is larger than a value of v/E of the stress relief layer, where v is a Poisson's ratio and E is a Young's modulus.

### FIELD

The present disclosure is generally related to structures and compositions for an information display. In particular, the present disclosure seeks to improve impact resistance of an information display, especially for use in mobile applications (e.g., cellular phone, tablet computer, notebook computer, etc.). An impact resistance information display according to the present disclosure may be applicable to displays such as light emitting diodes (LED) displays, organic LED (OLED) displays, quantum dot LED (QLED) displays, and the like.

### BACKGROUND

An information display device may include a stack of layers, for example, a matrix of organic light emitting diodes (OLEDs) disposed on a substrate, a touch sensor, and an optical polarizer. These layers may be bonded together using adhesive layers. The display device may further be bonded to a cover window, which light from the display device is emitted through and provides a physical protection of all layers in the display device. The display device may further be mounted into a housing, which typically supports the display device and provides protection of the layers of the display device on a surface opposite to the cover window and around edges or peripheral portions of the display device.

The information display devices may be foldable to allow for repeated shape changes during use(s). For example, these foldable display devices may be bent or folded such that at least a portion of the display device has a curvature at times and is substantially flat in other portion(s) of the display device. Deformable cover windows that do not fail (e.g., under cracking or yielding) and do not require a high force to deform are required for foldable display devices. Typically, such cover windows require to be thin in thickness and/or made of a material with low stiffness. For example, polymer materials may be a suitable window film or glass windows with a thickness below 100 μm may be suitable. In contrast to the foldable display devices, a relatively thick glass window (e.g., a thickness from 400 μm to 700 μm) is more suitable for non-bendable/non-foldable (e.g., where the shape of the display device does not change during use) display devices.

Display devices including thin cover windows or cover windows made of a material with low stiffness can be susceptible to damage, e.g., undergo large or significant deformations, due to impact from an object onto a window of a display device. To improve robustness of the display device against damage from impact, the surface of the display device opposite the cover window may be bonded to a shock absorber. However, even when a shock absorber is attached to the foldable display device, the robustness against impact is still significantly lower than a non-foldable display device having a thick glass cover window. Therefore, it is desirable to further increase the impact resistance of the foldable display device.

### SUMMARY

The present disclosure is directed to a foldable display device having improved impact resistance.

In accordance with a first aspect of the present disclosure, a foldable display device includes an organic light emitting diode (OLED) display substrate, a stress relief layer, and a first adhesive layer between the OLED display substrate and the stress relief layer. A value of v/E of the OLED display substrate is larger than a value of v/E of the stress relief layer, where v is a Poisson's ratio and E is a Young's modulus.

In an implementation of the first aspect, the foldable display device further includes a touch panel layer bonded to a side of the OLED display substrate opposite the stress relief layer by a second adhesive layer.

In another implementation of the first aspect, the foldable display device further includes a polarizing layer bonded to a side of the touch panel layer opposite the OLED display substrate by a third adhesive layer.

In yet another implementation of the first aspect, the value of v/E of the touch panel layer is larger than a value of v/E of the polarizing layer.

In yet another implementation of the first aspect, the value of v/E of the touch panel layer is larger than the value of v/E of the stress relief layer, and the value of v/E of the OLED display substrate is larger than the value of v/E of the polarizing layer.

In yet another implementation of the first aspect, the foldable display device further includes a cover window on a side of the polarizing layer opposite the touch panel layer.

In yet another implementation of the first aspect, the stress relief layer includes another polyimide having a molecular weight greater than the polyimide of the OLED display substrate, and the stress relief layer has a Young's modulus in a range of 6.5×10⁹ Pa to 8.0×10⁹ Pa and a Poisson's ratio in a range of 0.3 to 0.4.

In yet another implementation of the first aspect, the stress relief layer includes an ultra-thin glass having a Young's modulus in a range of 70×10⁹ Pa to 85×10⁹ Pa and a Poisson's ratio in a range of 0.19 to 0.25.

In yet another implementation of the first aspect, the stress relief layer includes polyethylene terephthalate (PET) having a Young's modulus in a range of 3.0×10⁹ Pa to 4.5×10⁹ Pa and a Poisson's ratio in a range of 0.33 to 0.35.

In yet another implementation of the first aspect, the polarizing layer includes polymethyl methacrylate (PMMA), and the polarizing layer has a Young's modulus in a range of 1.8×10⁹ Pa to 3.2×10⁹ Pa and a Poisson's ratio in a range of 0.35 to 0.40.

In yet another implementation of the first aspect, the third adhesive layer has a Young's modulus between 1.0×10⁵ Pa and 1.0×10⁶ Pa at room temperature.

In yet another implementation of the first aspect, a value of v/E of the touch panel layer and the value of v/E of the OLED display substrate are within 10% of each other.

In yet another implementation of the first aspect, the touch panel layer includes polymethyl methacrylate (PMMA).

In yet another implementation of the first aspect, the second adhesive layer has a Young's modulus less than 1.0×10⁵ Pa at room temperature.

In yet another implementation of the first aspect, the OLED display substrate and the touch panel layer include polyimide. The OLED display substrate and the touch panel layer have a same value of v/E and each has a Young's modulus in a range of 1.5×10⁹ Pa to 2.5×10⁹ Pa and a Poisson's ratio in a range of 0.3 to 0.4

In yet another implementation of the first aspect, the touch panel layer includes cyclic olefin copolymer (COC), and the touch panel layer has a Young's modulus in a range of 2.0×10⁹ Pa to 3.5×10⁹ Pa and a Poisson's ratio in a range of 0.30 to 0.42.

In yet another implementation of the first aspect, the foldable display device further includes a touch panel layer integrally formed with the OLED display substrate, and a polarizing layer bonded to a side of the OLED display substrate opposite the stress relief layer by a second adhesive layer similar to the first adhesive layer. A value of v/E of the OLED display substrate with the integrally formed touch panel layer is larger than a value of v/E of the polarizing layer and the value of v/E of the stress relief layer.

In yet another implementation of the first aspect, the stress relief layer is coplanar with the OLED display substrate.

In yet another implementation of the first aspect, the first adhesive layer has a Young's modulus between 1.0×10⁵ Pa and 1.0×10⁶ Pa at room temperature.

In yet another implementation of the first aspect, the OLED display substrate includes a polyimide, and has a Young's modulus in a range of 1.5×10⁹ Pa to 2.5×10⁹ Pa and a Poisson's ratio in a range of 0.3 to 0.4.

### BRIEF DESCRIPTION OF DRAWINGS

Aspects of the example disclosure are best understood from the following detailed description when read with the accompanying figures. Various features are not drawn to scale. Dimensions of various features may be arbitrarily increased or reduced for clarity of discussion.

FIG. 1A is a schematic diagram illustrating an object before subjecting to a compression load.

FIG. 1B is a schematic diagram illustrating expansion of the object in FIG. 1A under a compression load.

FIG. 2A is a schematic side view illustrating an object under a compression load.

FIG. 2B is a schematic side view of a plurality of layers before subjecting to a compression load.

FIG. 2C is a schematic side view of the plurality of layers in FIG. 2B under a compression load.

FIG. 3A is a schematic side view of a portion of an example foldable display device before subjecting to impact in accordance with an example implementation of the present disclosure.

FIG. 3B is a schematic side view of the portion of the example foldable display device in FIG. 3A under impact in accordance with an example implementation of the present disclosure.

FIG. 4A is a schematic side view of a portion of another example foldable display device before subjecting to impact in accordance with an example implementation of the present disclosure.

FIG. 4B is a schematic side view of the portion of the example foldable display device in FIG. 4A under impact in accordance with an example implementation of the present disclosure.

FIG. 5A is a schematic side view of a portion of another example foldable display device before subjecting to impact in accordance with an example implementation of the present disclosure.

FIG. 5B is a schematic side view of the portion of the example foldable display device in FIG. 5A under impact in accordance with an example implementation of the present disclosure.

### DESCRIPTION

The following disclosure contains specific information pertaining to example implementations in the present disclosure. The drawings in the present disclosure and their accompanying detailed description are directed to merely example implementations. However, the present disclosure is not limited to merely these example implementations. Other variations and implementations of the present disclosure will occur to those skilled in the art.

Unless noted otherwise, like or corresponding elements among the figures may be indicated by like or corresponding reference numerals. Moreover, the drawings and illustrations in the present disclosure are generally not to scale, and are not intended to correspond to actual relative dimensions.

For the purpose of consistency and ease of understanding, like features may be identified (although, in some examples, not shown) by the same numerals in the example figures. However, the features in different implementations may be differed in other respects, and thus shall not be narrowly confined to what is shown in the figures.

The description uses the phrases “in one implementation,” or “in some implementations,” which may each refer to one or more of the same or different implementations. The term “comprising” means “including, but not necessarily limited to” and specifically indicates open-ended inclusion or membership in the so-described combination, group, series, and the equivalent. The expression “at least one of A, B and C” or “at least one of the following: A, B and C” means “only A, or only B, or only C, or any combination of A, B and C.”

In various implementations of the present disclosure, a lamination layer may refer to a layer formed by a lamination process. However, it should be understood that a lamination layer may not be limited as such. For example, a lamination layer may be a layer formed over another layer, where the lamination layer may provide support, relieve stress, and/or provide rigidity for a display structure, but is not limited only to the examples provided herein.

Additionally, for the purposes of explanation and non-limitation, specific details, such as functional entities, techniques, protocols, standard, and the like are set forth for providing an understanding of the described technology. In other examples, detailed description of well-known methods, technologies, systems, architectures, and the like are omitted so as not to obscure the description with unnecessary details.

The present disclosure relates to a foldable display device, which is a structure for a foldable display panel, with properties of a plurality of layers configured to improve the robustness of the display panel against impact, for example, an impact on the viewing surface of the display panel by an external object. The foldable display device may include at least a display substrate such as an organic light emitting diode (OLED) display substrate. The foldable display device of the present disclosure is not limited to OLED, but may be applicable to other arrayed or LED subpixel devices, such as a Quantum dot LED (QLED) device or a micro-LED (mLED or μLED) device which may include a thin-film transistor backplane having an array of thin-film transistors to control light emissions for each subpixel of the plurality of subpixels in the foldable display device. The display device may further include at least one of a lamination layer (e.g., stress relief layer made of a polymer film having a thickness of approximately 50 μm) by which rigidity is improved to the display substrate, a touch sensor (e.g., a projected capacitive-type touch sensor, etc.), an optical polarizer (e.g., a circular polarizer, etc.), and a cover window (e.g., a polymer film having a thickness of approximately 100 μm). The layers as described above may be joined or bonded to each other and to the display substrate by relatively more flexible or bendable adhesive layers (e.g., optically clear adhesive, OCA). In a preferred implementation of the present disclosure, the foldable display device may include a lamination layer (e.g., stress relief layer), an OLED display substrate, a touch sensor or touch panel layer, an optical polarizer, and a cover window. The OLED display substrate may be parallel to, for example, disposed on, the lamination layer or stress relief layer. The touch sensor or touch panel layer may be disposed on a surface of the OLED display substrate opposite to the other surface of the OLED display substrate where the stress relief layer is located. The optical polarizer or a polarizer layer may be disposed on the touch panel layer. The cover window may be disposed on the polarizer layer. The foldable display device may also include at least one folding region (e.g., a hinge region of the foldable display device) and one or more non-folding regions (e.g., a planar region of the foldable display device).

During impact, the aforementioned layers in the foldable display device undergo compression due to the impact force imparted by an object onto the display device. If the object, which impacts the display device, has a relatively small contact surface area, such as that of a tip of a pen or stylus, the impact force on the display panel is confined to a relatively small area, which may lead to high stress on the panel layers. High stress may result in temporary or permanent damage to the display panel. Such high stress can temporarily or permanently deform the uppermost surface of the display panel, which may be distracting to users of the display device, particularly when an external source of light reflects off the uppermost surface of the display device. Such high stress may also damage the electronic components underneath the uppermost surface of the display device, such as the TFTs in an OLED display device, which may result in pixels being permanently on (“stuck” pixels) or permanently off (“dead” pixels) irrespective of the data supplied to the pixels. Any damage to the display device, such as the examples provided above, is highly undesirable and may result in an unstable and non-usable display for its intended purpose(s).

Moreover, for a display panel including a touch panel layer, high stress may cause permanent deformation to the touch panel layer. Such permanent deformation may result in non-uniform brightness (an undesirable property for a display device) of the display device around the point of impact when all pixels are configured to emit the same intensity of light because of light refraction within the display panel. The touch panel layer is particularly susceptible to deformation because the touch panel layer is often the least stiff and also being the thinnest layer among other layers in the display panel. Thus, it is necessary to prevent deformations, damages, or failures of the aforementioned layers.

In order to prevent permanent deformation or failure, one may design a display panel structure that may endure relatively high stress(es) from impact(s) by calculating a predicted value of von Mises stress for a layer or layers of the display panel structure before failure occurs and designing properties and arrangement of the layer(s) of the display panel structure that would not reach the predicted value of von Mises stress, thus preventing failures from occurring. The von Mises stress, σ_{von Mises}, may be represented by:

$${σ}_{von Mises} = \sqrt{\frac{1}{2} [ {( {σ}_{11} - {σ}_{22} )}^{2} + {( {σ}_{22} - {σ}_{33} )}^{2} + {( {σ}_{33} - {σ}_{11} )}^{2} + 6 ( {σ}_{12}^{2} + {σ}_{23}^{2} + {σ}_{31}^{2} ) ]} , \qquad Equation ( 1 )$$

where σ₁₁, σ₂₂, and σ₃₃ denote normal stresses (e.g., compressive stresses, conventionally having negative values), and σ₁₂, σ₂₃, and σ₃₁ denote shear stresses. By applying force(s) against the stress(es) that may be applied to the layer(s) of the foldable display device during an impact, the von Mises stress(es) is reduced or equalized, thus preventing failure or permanent deformation.

During impact, the shear stresses are typically small relative to the compressive stress, which infers that the assumption where shear stresses σ₁₂≈σ₂₃≈σ₃₁≈0 can be made, and that one of the principal stress directions lies along the direction of the impact. Thus, simplifying the Equation (1) above for the von Mises stress to Equation (2) represented by:

$${σ}_{von Mises} = \sqrt{\frac{1}{2} [ {( {σ}_{1} - {σ}_{2} )}^{2} + {( {σ}_{2} - {σ}_{3} )}^{2} + {( {σ}_{3} - {σ}_{1} )}^{2} ]} , \qquad Equation ( 2 )$$

where σ₁, σ₂, and σ₃ denote normal (e.g., compressive) stresses with reference to different coordinates (e.g., x, y, and z, where one co-ordinate is normal to the layer(s) of the display panel). Based on the Equation (2) above, the von Mises stress in a layer reduces if a compressive stress is applied to that layer perpendicular to the direction of the impact. Conversely, the von Mises stress increases if a tensile stress is applied to the layer perpendicular to the direction of impact.

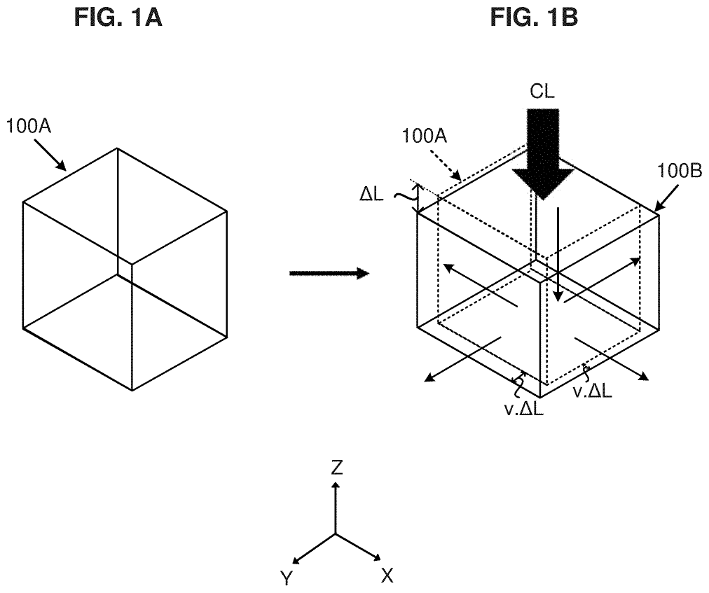

When a bulk material or an object is subject to a compression load (e.g., due to impact) along one axis, the bulk material will typically expand in the directions orthogonal to the axis. Such expansion is known as Poisson's effect and its magnitude is given by the Poisson's ratio, v, of the material (see FIG. 1B). If the material contracts by an amount of change in length (ΔL) in response to the compressive load of the impact, the material will expand by an amount of v.ΔL orthogonal to the direction of the impact (see FIG. 1B), where for most materials, the Poisson's ratio, v, is in the range: 0≤v≤0.5. For a given compressive load, ΔL (and hence v.ΔL) is inversely proportional to a value of Young's modulus, E, or relative stiffness, of the material.

In one or more implementations of the present disclosure, the layer or layers which are most prone to failure during impact are made predominantly from a material for which a value of v/E is higher than a value of v/E for a layer or layers adjacent (e.g., parallel) to the failure prone layer. During impact, all layers in the display panel are compressed, which causes the layers to try and expand in the orthogonal direction due to Poisson's effect. In one or more implementations of the present disclosure, adjacent layers (e.g., the OLED display panel and lamination layer) are bonded together by an adhesive. Therefore, the expansion of the layer with the larger value of v/E (e.g., the OLED display panel) is opposed by the relatively smaller expansion of the layer with the smaller value of v/E (e.g., lamination layer) because of the coupling between the layers caused by the adhesive. As such, the tensile stress, on the relatively more failure prone layer, that is orthogonal to the impact reduces and the von Mises stress also reduces in the layer which is most likely to fail (e.g., the OLED display panel), thus improving robustness to impact(s) of the display panel.

In a display panel with multiple layers that are impact sensitive layers adjacent to one another, for example, an OLED display substrate and an adjacent (e.g., parallel) layer that is also sensitive to impact, such as an adjacent touch panel layer, are stacked adjacent to each other, materials for adjacent and sensitive layers are preferred to be made of materials having closely matched (e.g., similar) values of v/E. The closely matched v/E values minimize the negative effect of the increased von Mises stress experienced by the layer with the smaller value of v/E, which has increased orthogonal stress due to greater expansion of the adjacent layer with the relatively larger value of v/E. In one implementation, v/E values of an OLED display substrate and an adjacent (e.g., parallel) touch panel layer are within 10% of each other. In another implementation, a v/E value of a touch panel layer is larger than a v/E value of a polarizer. In another implementation, the adjacent layers may be parallel to one another, and may also be coplanar with one another as long as the adjacent layers have no tilt angle with respect to one another. For example, the adjacent layers may be in the same layer, such as an integrated layer having both the adjacent layers.

FIG. 1A is a schematic diagram illustrating an object before subjecting to a compression load. FIG. 1B is a schematic diagram illustrating expansion of the object in FIG. 1A under a compression load.

In FIG. 1A, an object 100A is, for example, placed on a flat surface before a compression load is applied. When the object 100B in FIG. 1B is under a compression load CL (e.g., a force applied to the top surface in the negative Z direction), the object 100A (the dotted line object in FIG. 1B) is compressed. As compared to the object 100A, the compressed object 100B has a change in length (ΔL) along the z-axis (ΔL=σ/E), and expands by a change in length (v.ΔL) along the x-axis as well as a change in length (v.ΔL) along the y-axis (e.g., orthogonal to the compression load CL) due to Poisson's effect, where v is the Poisson's ratio of the material of the object 100A/100B.

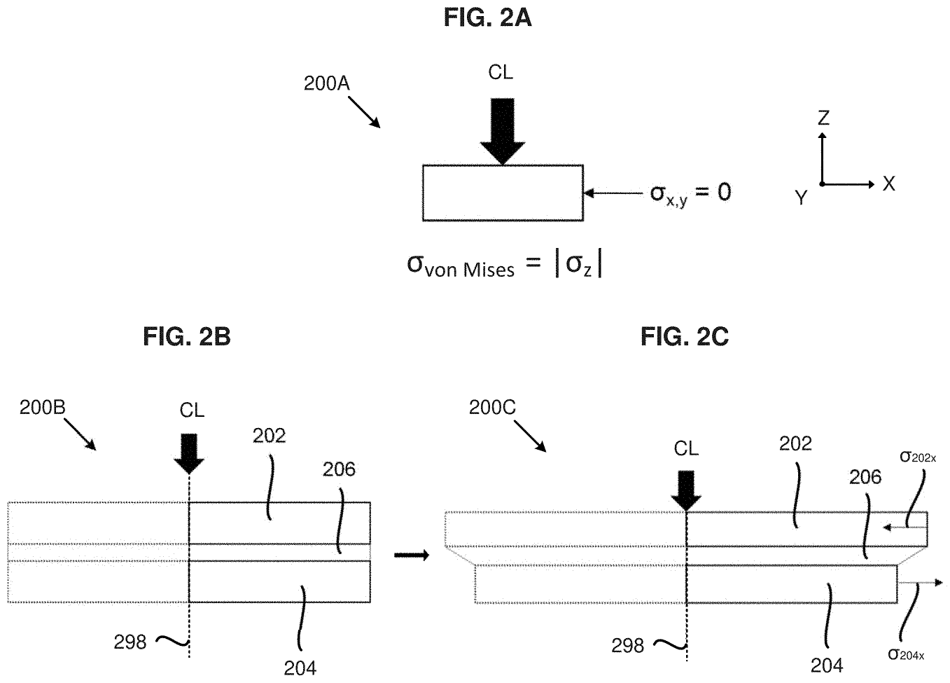

FIG. 2A is a schematic side view illustrating an object under a compression load. FIG. 2B is a schematic side view of a plurality of layers before subjecting to a compression load. FIG. 2C is a schematic side view of the plurality of layers in FIG. 2B under a compression load.

In FIG. 2A, an object 200A is under a compression load CL (e.g., a force applied to the top surface in the negative z-direction), for example, due to an impact, resulting in a compressive stress, σ_{z}. It should be noted that, by convention, σ_{z} may have a negative value due to the compressive load. The object 200A is not under compressive stress along the x-direction and y-direction (e.g., σ_{x,y}=0 in the x-direction and y-direction), and may freely expand in directions orthogonal to the compression load CL.

In FIG. 2B, a structure 200B including a plurality of layers, such as two rigid layers 202, 204, may be bonded together by a relatively less rigid adhesive layer 206 therebetween before a compressive load CL (e.g., impact) is applied. The compressive load CL may be applied along the center line 298 (represented by a dotted line) of the structure 200B. The two rigid layers 202, 204 may have different values of Poisson's ratio v and Young's Modulus E, thus having different values of v/E and different extent of physical behavior under the same amount of stress. When a compressive load CL (e.g., a uniaxial stress due to impact) is applied to the center line 298 of the structure 200B, the structure 200B may undergo physical changes and result in a structure similar to structure 200C in FIG. 2C. In FIG. 2C, the two rigid layers 202, 204 with the adhesive layer 206 between may undergo stress from the compressive load CL and react differently. The physical behaviors of the plurality of layers of the structures 200B and 200C may be identical on both sides of the center line 298 of the structures 200B and 200C, thus the physical behaviors of the layers of the structure 200C under stress on one side of the center line 298 are described for brevity. Due to the different values in v/E for the two rigid layers 202, 204 and the coupling of the two rigid layers 202, 204 by the adhesive layer 206, the two rigid layers 202, 204 physically behave differently and to different extents. In one example, the rigid layer 204 may have a lower v/E value (e.g., v₂₀₄/E₂₀₄) relative to the larger v/E value (v₂₀₂/E₂₀₂) of the rigid layer 202 (e.g., v₂₀₄/E₂₀₄<v₂₀₂/E₂₀₂). When the compressive load CL is applied to the structure 200C, the rigid layer 204 having the relatively lower v₂₀₄/E₂₀₄ value may apply a stress σ₂₀₂ₓ (e.g., a negative stress or a stress in a negative x-direction) on the rigid layer 202 against the expansion of the rigid layer 202 (e.g., in a positive x-direction), which reduces the overall von Mises stress applied to the rigid layer 202, while the rigid layer 202 may apply a stress σ₂₀₄ₓ (e.g., a positive stress or a stress in a positive x-direction) on the rigid layer 204 against the contraction of the rigid layer 204 (e.g., in a negative x-direction). The expansion of the rigid layer 202 is reduced relative to free expansion due to the stress σ₂₀₂ₓ experienced by the rigid layer 202 and applied by the rigid layer 204 via the adhesive layer 206, thus the overall von Mises stress applied to the rigid layer 202 is also reduced relative to the von Mises stress under free expansion. Conversely, the stress σ₂₀₄ₓ applied by the rigid layer 202 and exerted on the rigid layer 204 via the adhesive layer 206 increases the von Mises stress applied to the rigid layer 204. Although the von Mises stress applied to the rigid layer 204 increases, the rigid layer 204 may be designed to be a relatively more rigid layer than the rigid layer 202, thus the rigid layer 204 provides improved impact resistance to the overall structure 200C.

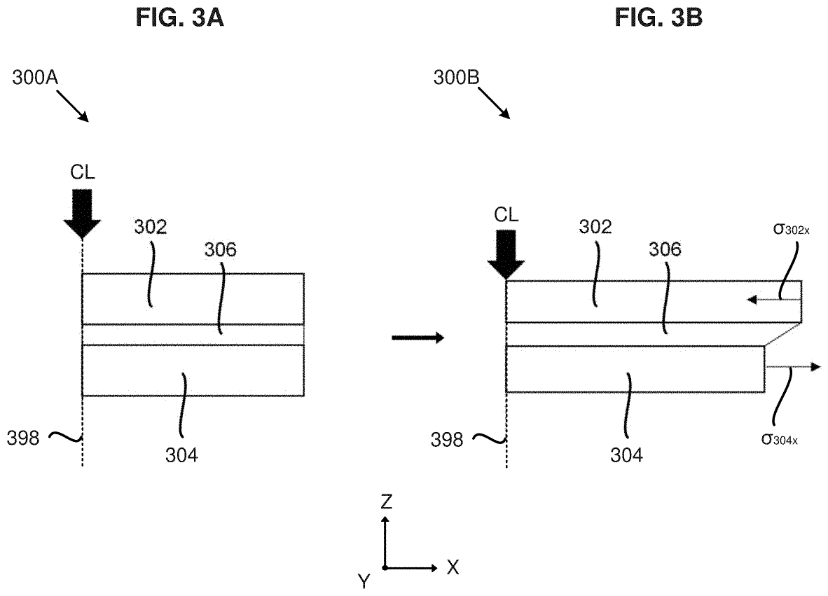

FIG. 3A is a schematic side view of a portion of an example foldable display device before subjecting to impact in accordance with an example implementation of the present disclosure. FIG. 3B is a schematic side view of the portion of the example foldable display device in FIG. 3A under impact in accordance with an example implementation of the present disclosure. The layers of each of the example structures 300A and 300B for a foldable display device may be identical on both sides of a center line 398 (represented by a dotted line) of the structures 300A, 300B, thus only one side of the structures 300A, 300B with respect to the center line 398 are described for brevity.

In FIG. 3A, the example structure 300A of a foldable display device in one or more implementations may include an OLED display substrate 302, a stress relief layer 304, and an adhesive layer 306 bonding the OLED display substrate 302 and the stress relief layer 304 therebetween. The adhesive layer 306 may be less rigid than both the OLED display substrate 302 and the stress relief layer 304. The stress relief layer 304 may be more rigid than the OLED display substrate 302. The stress relief layer 304 may be bonded to a non-viewing side of the OLED display substrate 302 via the adhesive layer 306 and may be made of a material that has a lower v/E value (e.g., v₃₀₄/E₃₀₄) relative to a higher v/E value (e.g., v₃₀₂/E₃₀₂) of the material of the OLED display substrate 302 (e.g., v₃₀₄/E₃₀₄<v₃₀₂/E₃₀₂). In one or more implementations, the OLED display substrate 302, on which electronic components may be disposed and encapsulated, may be made from a material including polyimide with a Young's Modulus (E), for example E₃₀₂, in the range of 1.5 GPa to 6.5 GPa and a Poisson's ratio (v), for example v₃₀₂, in the range of 0.3 to 0.4. In one preferred implementation, the OLED display substrate 302 may be made of polyimide. In one implementation, the OLED display substrate 302 may be made of plastics, ultra-thin foils (e.g., stainless steel) or ultra-thin ceramics (e.g., zirconia-based ceramics). The term “ultra-thin” may refer to a thickness of less than 40 microns, and possibly about 20-25 microns.

The stress relief layer 304 may be made from a material including polyimide with a higher molecular weight and/or additional long-chain branches than that of the OLED display substrate and with an E (e.g., E₃₀₄) value in the range 6.5 GPa to 8.0 GPa and a v (e.g., v₃₀₄) value in the range of 0.3 to 0.4. In another implementation, ultrathin glasses having an E (e.g., E₃₀₄) value in the range of 70 GPa to 85 GPa and a v (e.g., v₃₀₄) value in the range of 0.19 to 0.25 may be used as the stress relief layer 304. In yet another implementation, the stress relief layer 304 (e.g., a lamination layer) may be made of polyethylene terephthalate (PET) with an E value in the range of 3.0 GPa to 4.5 GPa and a v value in the range 0.33 to 0.35. The E value may be modified, for example, by adding 15% glass fibres to the PET to increase the E value to between 4.5 GPa and 7.0 GPa. The E value may be further increased by increasing the percentage of glass fibres in the PET while the v value may not be substantially affected by the inclusion of glass fibres.

The ultrathin glass may effectively reduce the von Mises stress in the OLED display substrate, thus reducing the risk of failure of the OLED pixels in the OLED display substrate, especially when the foldable display device is under stress (e.g., compression load or impact). The values of E and v for the stress relief layer and the OLED display substrate are not limited to only the example values provided herein as long as the essential principles of the present disclosure remain.

In FIG. 3B, an example structure 300B of a foldable display device may include an OLED display substrate 302, a stress relief layer 304, and an adhesive layer 306 similar to the OLED display substrate 302, the stress relief layer 304, and the adhesive layer 306, respectively, of the example structure 300A, however, differ in that the example structure 300B of the foldable display device in FIG. 3B is under stress (e.g., a compression load CL or impact in the negative Z direction).

Similar to the example structure 300A, the OLED display substrate 302 of the example structure 300B may have a higher v/E value (e.g., v₃₀₂/E₃₀₂) relative to a lower v/E value (e.g., v₃₀₄/E₃₀₄) of the stress relief layer 304 of the example structure 300B, and the adhesive layer 306 may bond the OLED display substrate 302 to the stress relief layer 304. With such properties and arrangement, when the compressive load CL is applied to the example structure 300B, the stress relief layer 304 having the v₃₀₄/E₃₀₄ value may apply a stress σ₃₀₂ₓ (e.g., in a negative x-direction) on the OLED display substrate 302 against the expansion of the OLED display substrate 302 (e.g., in a positive x-direction) while the OLED display substrate 302 may apply a stress σ₃₀₄ₓ (e.g., in a positive x-direction) on the stress relief layer 304 against the contraction of the stress relief layer 304 (e.g., in a negative x-direction). The expansion of OLED display substrate 302 is reduced relative to free expansion due to the stress σ₃₀₂ₓ experienced by the OLED display substrate 302 and applied by the stress relief layer 304 via the adhesive layer 306, thus the von Mises stress applied to the OLED display substrate 302 may also be reduced relative to the von Mises stress under free expansion. Conversely, the stress σ₃₀₄ₓ applied by the OLED display substrate 302 via the adhesive layer 306 and exerted on the stress relief layer 304 may increase the von Mises stress applied to the stress relief layer 304. Although the von Mises stress applied to the stress relief layer 304 increases, the stress relief layer 304 may be designed to be a relatively more rigid layer than the OLED display substrate 302, thus the stress relief layer 304 may relieve the tensile stress from the OLED display substrate 302 and lower the risk of failure on the most sensitive layer, the OLED display substrate 302, among all layers of the example structure 300B. Therefore, improving impact resistance to the overall example structure 300B of a foldable display device.

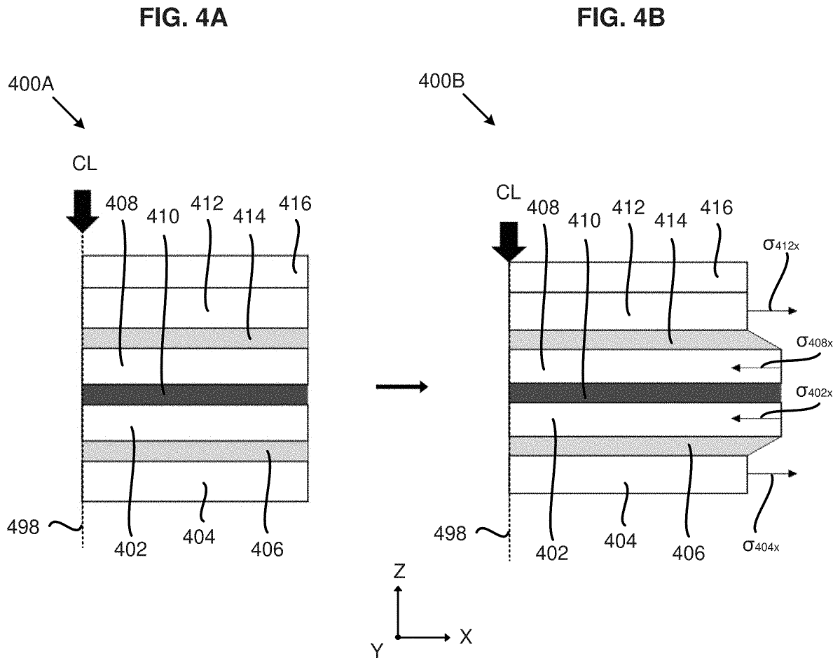

FIG. 4A is a schematic side view of a portion of another example foldable display device before subjecting to impact in accordance with an example implementation of the present disclosure. FIG. 4B is a schematic side view of the portion of the example foldable display device in FIG. 4A under impact in accordance with an example implementation of the present disclosure. The layers of each of the example structures 400A and 400B for a foldable display device in FIGS. 4A and 4B are identical on both sides of a center line 498 of the structures 400A, 400B, thus only one side of the structures 400A, 400B with respect to the center line 498 are described for brevity.

In FIG. 4A, the example structure 400A of a foldable display device may include an OLED display substrate 402, a stress relief layer 404, and an adhesive layer 406 similar to the OLED display substrate 302, the stress relief layer 304, and the adhesive layer 306, respectively, of the example structure 300A in FIG. 3A. Thus, details of these layers are omitted for brevity.

The example structure 400A of the foldable display device in FIG. 4A may be different from the example structure 300A in FIG. 3A in that the example structure 400A may further include a touch panel layer 408 bonded to a side of the OLED display substrate 402 opposite the stress relief layer 404 by another adhesive layer 410, a polarizing layer 412 bonded to a side of the touch panel layer 408 opposite the OLED display substrate 402 by yet another adhesive layer 414, and a cover window (e.g., a clear film) 416 disposed on a side of the polarizing layer 412 opposite the touch panel layer 408. In one implementation, the cover window 416 may be bonded to the polarizing layer 412 by an adhesive layer (not explicitly shown) similar to any of the adhesive layers 406, 414.

In one or more implementations of the present disclosure, the adhesive layers 406, 410, and 414 may be less rigid than the OLED display substrate 402, the stress relief layer 404, the touch panel layer 408, the polarizing layer 412, and the cover window 416. The stress relief layer 404 may be more rigid than the OLED display substrate 402. The touch panel layer 408 and the OLED display substrate 402 may be the most sensitive (e.g., prone to failure due to impact) layers among all layers of the example structure 400A. The OLED display substrate 402 may be made of a material that has a higher value of v/E (e.g., v₄₀₂/E₄₀₂) relative to a lower value of v/E (e.g., v₄₀₄/E₄₀₄) of the material of the stress relief layer 404 (e.g., v₄₀₂/E₄₀₂>v₄₀₄/E₄₀₄) and the touch panel layer 408 may be made of a material that has a higher value of v/E (e.g., v₄₀₈/E₄₀₈) relative to a lower value of v/E (e.g., v₄₁₂/E₄₁₂) of the material of the polarizing layer 412 (e.g., v₄₀₈/E₄₀₈>v₄₁₂/E₄₁₂).

In a preferred implementation, the value of v₄₀₂/E₄₀₂ of the OLED display substrate 402 and the value of v₄₀₈/E₄₀₈ of the adjacent touch panel layer 408 are closely matched (e.g., v₄₀₂/E₄₀₂≈v₄₀₈/E₄₀₈). In another implementation, the value of v₄₀₂/E₄₀₂ of the OLED display substrate 402 and the value of v₄₀₈/E₄₀₈ of the adjacent touch panel layer 408 are within 10% of each other.

In the preferred implementation, the OLED display substrate 402 and the touch panel layer 408 may be made of a material that has a higher a v/E value relative to a v/E value of the material of the stress relief layer 404 and the polarizing layer 412, for example, v₄₀₂/E₄₀₂ and v₄₀₈/E₄₀₈>v₄₀₄/E₄₀₄ and/or v₄₁₂/E₄₁₂. In another example, v₄₀₂/E₄₀₂>v₄₀₄/E₄₀₄ and v₄₀₈/E₄₀₈>v₄₁₂/E₄₁₂.

In the preferred implementation, the adhesive layer 410 has a lower value of E₄₁₀ (e.g., softer) than the E values (e.g., E₄₀₆, E₄₁₄) of the adhesive layers 406, 414 (e.g., E₄₁₀<E₄₀₆ E₄₁₄).

In one preferred implementation, the example structure 400A of the foldable display device may include the OLED display substrate 402 between the stress relief layer 404 and the touch panel layer 408, the polarizing layer 412 on the touch panel layer 408, and the cover window 416 on the polarizing layer 412. In the preferred implementation, the OLED display substrate 402 and touch panel layer 408 are adjacent to each other and have a similar value of v/E (v₄₀₂/E₄₀₂≈v₄₀₈/E₄₀₈). For example, the OLED display substrate 402 and the touch panel layer 408 may be made of the same material, such as colourless polyimide with an E (e.g., E₄₀₂ or E₄₀₈) value in the range 1.5 GPa to 2.5 GPa and a v (v₄₀₂ or v₄₀₈) value in the range 0.3 to 0.4. In another implementation, the touch panel layer 408 may be made of cyclic olefin copolymer (also known as COC or COP) with an E value in the range 2.0 GPa to 3.5 GPa and a v value in the range 0.3 to 0.42. In one or more implementations, the polarizing layer 412 made be made of a material including polymethyl methacrylate (PMMA) with an E (e.g., E₄₁₂) value in the range 1.8 GPa to 3.2 GPa and a v (e.g., v₄₁₂) value in the range 0.35 to 0.4. The values of E and v for the polarizing layer 412 are not limited to only the example values provided herein. In another implementation, the polarizing layer 412 may be made of a thin-film “coating” polarizer, in which a layer or layers of polyvinyl alcohol (PVA) is applied to a substrate of a different material. The substrate material may be optically transparent (for example, PET). The “coating” polarizer may allow mechanical properties of the substrate to be prioritized to provide a structure with high impact resistance. In another implementation, the touch panel layer 408 may be made of PMMA. A short-chain PMMA, which has a lower E value, may be used for the touch panel layer 408, while a long-chain PMMA, which has higher E value, may be used for the polarizing layer 412.

In FIG. 4B, an example structure 400B of a foldable display device may include an OLED display substrate 402, a stress relief layer 404, and an adhesive layer 406 similar to the OLED display substrate 302, the stress relief layer 304, and the adhesive layer 306, respectively, of the example structure 300B, however, differ in that the example structure 400B of the foldable display device in FIG. 4B further include the touch panel layer 408, the polarizing layer 412, the cover window 416, and the adhesives layers 410, 414.

In one or more implementations of the present disclosure, the OLED display substrate 402 of the example structure 400B may have a value of v₄₀₂/E₄₀₂ similar to a value of v₄₀₄/E₄₀₄ of the stress relief layer 404 of the example structure 400B, and the “softer” adhesive layer 410 may help prevent stress propagation mutually applied by the OLED display substrate 402 and the touch panel layer 408. With the layer arrangement and properties of the example structure 400B, when the compressive load CL is applied to the example structure 400B at a center line 498, the stress relief layer 404 having the relatively lower v₄₀₄/E₄₀₄ value may apply a stress σ₄₀₂ₓ (e.g., in a negative x-direction) on the OLED display substrate 402 against the expansion of the OLED display substrate 402 (e.g., in a positive x-direction) while the OLED display substrate 402 may apply a stress σ₄₀₄ₓ (e.g., in a positive x-direction) on the stress relief layer 404 against the contraction of the stress relief layer 404 (e.g., in a negative x-direction). The expansion of OLED display substrate 402 is reduced relative to free expansion due to the stress σ₄₀₂ₓ experienced by the OLED display substrate 402 and applied by the stress relief layer 404 via the adhesive layer 406, thus the von Mises stress applied to the OLED display substrate 402 may also be reduced relative to the von Mises stress under free expansion. Conversely, the stress σ₄₀₄ₓ applied by the OLED display substrate 402 via the adhesive layer 406 and exerted on the stress relief layer 404 may increase the von Mises stress applied to the stress relief layer 404. Although the von Mises stress applied to the stress relief layer 404 increases, the stress relief layer 404 may be designed to be a relatively more rigid layer than the OLED display substrate 402, thus the stress relief layer 404 may relieve the tensile stress from the OLED display substrate 402 and lower the risk of failure on the most sensitive layer, the OLED display substrate 402, among all layers of the example structure 400B. Therefore, improving impact resistance to the overall example structure 400B of a foldable display device. Similar to the OLED display substrate 402 and the adjacent stress relief layer 404 of the example structure 400B, the touch panel layer 408 and the adjacent polarizing layer 412 of the example structure 400B may exhibit similar physical changes due to similar stresses (σ₄₀₈ₓ and σ₄₁₂ₓ) as shown in FIG. 4B and predicted by the Poisson's effect. Thus, the adjacent layers (e.g., the stress relief layer 404 and the polarizing layer 412) may provide sufficient opposition to the Poisson expansion of the sensitive layers (e.g., the OLED display substrate 402 and the touch panel layer 408) and lower the von Mises stress of the example structure 400B for a foldable display device. In other words, in one or more implementations, the stress relief layer 404 and the polarizing layer 412 are made of materials having lower v/E values than the v/E values of the OLED display substrate 402 and the touch panel layer 408, respectively (e.g., v₄₀₄/E₄₀₄<v₄₀₂/E₄₀₂ and v₄₁₂/E₄₁₂<v₄₀₈/E₄₀₈).

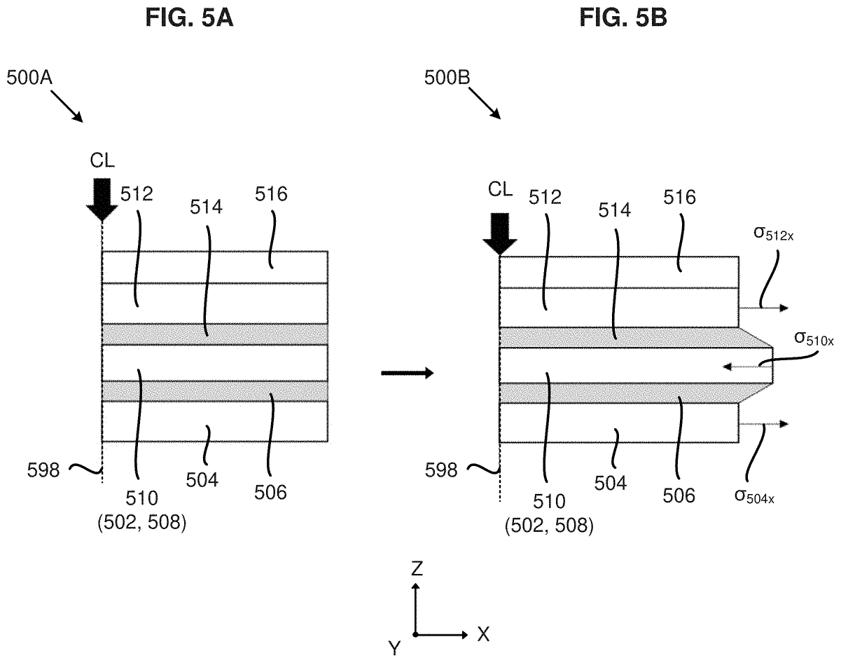

FIG. 5A is a schematic side view of a portion of another example foldable display device before subjecting to impact in accordance with an example implementation of the present disclosure. FIG. 5B is a schematic side view of the portion of the example foldable display device in FIG. 5A under impact in accordance with an example implementation of the present disclosure. The layers of each of the example structures 500A and 500B for a foldable display device in FIGS. 5A and 5B are identical on both sides of a center line 598 (represented by a dotted line) of the structures 500A, 500B, thus only one side of the structures 500A, 500B with respect to the center line 598 are described for brevity.

In FIG. 5A, the example structure 500A of a foldable display device may include an OLED display substrate 502, a stress relief layer 504, an adhesive layer 506 between the OLED display substrate 502 and the stress relief layer 504, a touch panel layer 508, a polarizing layer 512, another adhesive layer 514, and a cover window 516 on the polarizing layer 512 similar to the OLED display substrate 402, the stress relief layer 404, the adhesive layer 406 between the OLED display substrate 402 and the stress relief layer 404, the touch panel layer 408, the polarizing layer 412, another adhesive layer 414, and the cover window 416 on the polarizing layer 412, respectively, of the example structure 400A in FIG. 4A. Thus, details of these layers are omitted for brevity.

The example structure 500A of the foldable display device in FIG. 5A may be different from the example structure 400A in FIG. 4A in that the example structure 500A may further integrate the touch panel layer 508 with the OLED display substrate 502 into one element or layer 510 and removing an adhesive layer between the touch panel layer 508 and the OLED display substrate 502. In one preferred implementation, the example structure 500A may include the adhesive layer 506 bonded between the integrated touch panel layer/OLED display substrate element 510 and the stress relief layer 504, the polarizing layer 512 bonded on a side of the integrated touch panel layer/OLED display substrate element 510 opposite to the stress relief layer 504 by another adhesive layer 514, and the cover window 516 disposed on a side of the polarizing layer 512 opposite the integrated touch panel layer/OLED display substrate element 510. In one implementation, the cover window 516 may be disposed on the polarizing layer 512 by bonding via another adhesive layer (not explicitly shown) similar to the adhesive layers 506, 514.

In one or more implementations of the present disclosure, the adhesive layers 506, 514 may be less rigid than the integrated touch panel layer/OLED display substrate element 510, the stress relief layer 504, the polarizing layer 512, and the cover window 516. The stress relief layer 504 and the polarizing layer 512 may be more rigid than the integrated touch panel layer/OLED display substrate element 510 (the most sensitive, for example, most prone to failure due to impact) among all layers of the example structure 500A. In the preferred implementation, the integrated touch panel layer/OLED display substrate element 510 may be made of a material that has a higher v/E (e.g., v₅₁₀/v₅₁₀) value relative to the v/E (e.g., v₅₀₄/E₅₀₄ and v₅₁₂/E₅₁₂) values of the materials of the stress relief layer 504 and polarizing layer 512. For example, v₅₁₀/E₅₁₀>v₅₀₄/E₅₀₄ and v₅₁₂/E₅₁₂. In one or more implementations, the integrated touch panel layer/OLED display substrate element 510 may be a combination of the functionalities of the touch panel layer 508 integrated into the OLED display substrate 502 by disposing the touch panel components either directly onto the outer surface of the thin-film encapsulation of the OLED (on-cell) display substrate 502 or below the thin-film encapsulation (in-cell). Such example implementations eliminate the need for a separate touch panel layer, resulting in a preferred structure of an adhesive layer 506 bonded between the integrated touch panel layer/OLED display substrate element 510 and the stress relief layer 504, the polarizing layer 512 bonded on a side of the integrated touch panel layer/OLED display substrate element 510 opposite to the stress relief layer 504 by another adhesive layer 514, and the cover window 516 disposed on a side of the polarizing layer 512 opposite the integrated touch panel layer/OLED display substrate element 510. The materials and properties for the OLED display substrate, the touch panel layer, the stress relief layer, the polarizing layer, and the cover window in the descriptions of FIGS. 4A and 4B may also be applied to the present implementation, thus are omitted for brevity.

In FIG. 5B, an example structure 500B of a foldable display device may include an integrated touch panel layer (502)/OLED display substrate (508) element 510, a stress relief layer 504, an adhesive layer 506, a polarizing layer 512, another adhesive layer 514, and a cover window 516 similar to the integrated touch panel layer (502)/OLED display substrate (508) element 510, the stress relief layer 504, the adhesive layer 506, the polarizing layer 512, the other adhesive layer 514, and the cover window 516 of the example structure 500A, however, differ in that the example structure 500B of the foldable display device in FIG. 5B is under stress (e.g., a compression load CL or impact).

In one or more implementations of the present disclosure, the integrated touch panel layer/OLED display substrate element 510 of the example structure 500B may have a v/E value (e.g., v₅₁₀/E₅₁₀) greater than v/E values (e.g., v₅₀₄/E₅₀₄ and v₅₁₂/E₅₁₂) of the stress relief layer 504 and the polarizing layer 512 of the example structure 500B (e.g., v₅₁₀/E₅₁₀>v₅₀₄/E₅₀₄ and v₅₁₂/E₅₁₂). With the layer arrangement and properties of the example structure 500B, when the compressive load CL is applied to the example structure 500B at a center line 598, the stress relief layer 504 having the relatively lower v/E value (e.g., v₅₀₄/E₅₀₄) may apply a stress σ₅₁₀ₓ (e.g., in a negative x-direction) on the integrated touch panel layer/OLED display substrate element 510 against the expansion of the integrated touch panel layer/OLED display substrate element 510 (e.g., in a positive x-direction) while the integrated touch panel layer/OLED display substrate element 510 may apply a stress σ₅₀₄ₓ (e.g., in a positive x-direction) on the stress relief layer 504 against the contraction of the stress relief layer 504 (e.g., in a negative x-direction). The expansion of the integrated touch panel layer/OLED display substrate element 510 is reduced relative to free expansion due to the stress σ₅₁₀ₓ experienced by the integrated touch panel layer/OLED display substrate element 510 and applied by the stress relief layer 504 via the adhesive layer 506, thus the von Mises stress applied to the integrated touch panel layer/OLED display substrate element 510 may also be reduced relative to the von Mises stress under free expansion. Conversely, the stress σ₅₀₄ₓ applied by the integrated touch panel layer/OLED display substrate element 510 via the adhesive layer 506 and exerted on the stress relief layer 504 may increase the von Mises stress applied to the stress relief layer 504. Although the von Mises stress applied to the stress relief layer 504 increases, the stress relief layer 504 may be designed to be a relatively more rigid layer than the integrated touch panel layer/OLED display substrate element 510, thus the stress relief layer 504 may relieve the tensile stress from the integrated touch panel layer/OLED display substrate element 510 and lower the risk of failure on the most sensitive layer, the integrated touch panel layer/OLED display substrate element 510, among all layers of the example structure 500B. Therefore, improving impact resistance to the overall example structure 500B of a foldable display device. Similar to the integrated touch panel layer/OLED display substrate element 510 and the adjacent stress relief layer 504 of the example structure 500B, the integrated touch panel layer/OLED display substrate element 510 and the adjacent polarizing layer 512 of the example structure 500B may exhibit similar physical changes due to similar stresses (e.g., σ₅₁₀ₓ and σ₅₁₂ₓ) as shown in FIG. 5B and predicted by the Poisson's effect. Thus, the adjacent layers (e.g., the stress relief layer 504 and the polarizing layer 512) may provide sufficient opposition to the Poisson expansion of the sensitive layer (e.g., the integrated touch panel layer/OLED display substrate element 510) and lower the von Mises stress of the example structure 500B for a foldable display device. In other words, in one or more implementations, the adjacent stress relief layer 504 and the adjacent polarizing layer 512 are made of materials having lower values of v/E than that of the integrated touch panel layer/OLED display substrate element 510 (e.g., v₅₀₄/E₅₀₄<v₅₁₀/E₅₁₀ and v₅₁₂/E₅₁₂<v₅₁₀/E₅₁₀).

Thus, the adjacent layers may reduce von Mises stress and the risk of failure for the most sensitive layer (e.g., the OLED display substrate and touch panel integrated layer) in the structure 500B of the foldable display device, and therefore effectively providing impact resistance.

In one or more implementations, the amount of von Mises stress that is reduced (or increased) in a target layer (e.g., an OLED display substrate or a touch panel layer) is determined by the degree of coupling between a stress relief layer (e.g., or a polarizing layer) and the target layer. The coupling effect is maximized when the stress relief layer and the target layer are rigidly bonded by an adhesive that does not allow slippage therebetween. Conversely, the coupling effect is minimized if the stress relief layer and the target layer are not bonded together, can freely slip over one another, and opposed each other only by friction.

In one or more implementations, the advantageous effect as mentioned above that may be achieved by choice of materials with specific values of v/E may be maximized by using an adhesive layer with a relatively higher Young's modulus between a layer vulnerable to impact failure and a layer which is not (e.g., an adhesive layer between a lamination layer and an OLED display substrate and/or between a touch panel layer and a polarizer). As for display device structures having two vulnerable layers adjacent to one another, such as an OLED display substrate adjacent to a touch panel layer, it may be advantageous to apply an adhesive with a relatively lower Young's modulus (e.g., soft adhesive) between the two vulnerable layers to minimize force interaction therebetween.

In one or more implementations, the Young's modulus of the adhesive layers must be sufficiently low to enable folding without causing failures such as creasing, buckling or delamination. A suitable higher Young's modulus adhesive may have a Young's modulus in the range of 1.0×10⁵ Pa to 1.0×10⁶ Pa at room temperature while a suitable lower Young's modulus adhesive may have a Young's modulus in the range of 1.0×10⁴ Pa to 1.0×1.0⁵ Pa at room temperature.

The values of Poisson's ratio (v), Young's modulus (E), and v/E should not be limited to the example values provided herein as long as the essential principle of the present disclosure could be applied.

From the present disclosure, it can be seen that various techniques may be used for implementing the concepts described in the present disclosure without departing from the scope of those concepts. While the concepts have been described with specific reference to certain implementations, a person of ordinary skill in the art may recognize that changes may be made in form and detail without departing from the scope of those concepts. As such, the described implementations are to be considered in all respects as illustrative and not restrictive. It should also be understood that the present disclosure is not limited to the particular implementations described but rather many rearrangements, modifications, and substitutions are possible without departing from the scope of the present disclosure.

What is claimed is:

1. A foldable display device, comprising:
an organic light emitting diode (OLED) display substrate;
a stress relief layer; and
a first adhesive layer between the OLED display substrate and the stress relief layer;
wherein a value of v/E of the OLED display substrate is larger than a value of v/E of the stress relief layer, where v is a Poisson's ratio and E is a Young's modulus.

2. The foldable display device of claim 1, further comprising:
a touch panel layer bonded to a side of the OLED display substrate opposite the stress relief layer by a second adhesive layer.

3. The foldable display device of claim 2, further comprising:
a polarizing layer bonded to a side of the touch panel layer opposite the OLED display substrate by a third adhesive layer.

4. The foldable display device of claim 3, wherein:
the value of v/E of the touch panel layer is larger than a value of v/E of the polarizing layer.

5. The foldable display device of claim 4, wherein:
the value of v/E of the touch panel layer is larger than the value of v/E of the stress relief layer; and
the value of v/E of the OLED display substrate is larger than the value of v/E of the polarizing layer.

6. The foldable display device of claim 3, further comprising:
a cover window on a side of the polarizing layer opposite the touch panel layer.

7. The foldable display device of claim 1, wherein:
the stress relief layer comprises another polyimide having a molecular weight greater than the polyimide of the OLED display substrate; and
the stress relief layer has a Young's modulus in a range of 6.5×10⁹ Pa to 8.0×10⁹ Pa and a Poisson's ratio in a range of 0.3 to 0.4.

8. The foldable display device of claim 1, wherein:
the stress relief layer comprises an ultra-thin glass having a Young's modulus in a range of 70×10⁹ Pa to 85×10⁹ Pa and a Poisson's ratio in a range of 0.19 to 0.25.

9. The foldable display device of claim 1, wherein:
the stress relief layer comprises polyethylene terephthalate (PET) having a Young's modulus in a range of 3.0×10⁹ Pa to 4.5×10⁹ Pa and a Poisson's ratio in a range of 0.33 to 0.35.

10. The foldable display device of claim 3, wherein:
the polarizing layer comprises polymethyl methacrylate (PMMA); and
the polarizing layer has a Young's modulus in a range of 1.8×10⁹ Pa to 3.2×10⁹ Pa and a Poisson's ratio in a range of 0.35 to 0.40.

11. The foldable display device of claim 3, wherein the third adhesive layer has a Young's modulus between 1.0×10⁵ Pa and 1.0×10⁶ Pa at room temperature.

12. The foldable display device of claim 2, wherein a value of v/E of the touch panel layer and the value of v/E of the OLED display substrate are within 10% of each other.

13. The foldable display device of claim 2, wherein:
the touch panel layer comprises polymethyl methacrylate (PMMA).

14. The foldable display device of claim 2, wherein the second adhesive layer has a Young's modulus less than 1.0×10⁵ Pa at room temperature.

15. The foldable display device of claim 2, wherein:
the OLED display substrate and the touch panel layer comprise polyimide; and
the OLED display substrate and the touch panel layer have a same value of v/E and each has a Young's modulus in a range of 1.5×10⁹ Pa to 2.5×10⁹ Pa and a Poisson's ratio in a range of 0.3 to 0.4.

16. The foldable display device of claim 2, wherein:
the touch panel layer comprises cyclic olefin copolymer (COC); and
the touch panel layer has a Young's modulus in a range of 2.0×10⁹ Pa to 3.5×10⁹ Pa and a Poisson's ratio in a range of 0.30 to 0.42.

17. The foldable display device of claim 1, further comprising:
a touch panel layer integrally formed with the OLED display substrate; and
a polarizing layer bonded to a side of the OLED display substrate opposite the stress relief layer by a second adhesive layer similar to the first adhesive layer;
wherein a value of v/E of the OLED display substrate with the integrally formed touch panel layer is larger than a value of v/E of the polarizing layer and the value of v/E of the stress relief layer.

18. The foldable display device of claim 1, wherein:
the stress relief layer is coplanar with the OLED display substrate.

19. The foldable display device of claim 1, wherein the first adhesive layer has a Young's modulus between 1.0×10⁵ Pa and 1.0×10⁶ Pa at room temperature.

20. The foldable display device of claim 1, wherein:
the OLED display substrate comprises a polyimide, and has a Young's modulus in a range of 1.5×10⁹ Pa to 2.5×10⁹ Pa and a Poisson's ratio in a range of 0.3 to 0.4.
